(19) United States
(12) Patent Application Publication
(10) Pub. No.: US 2011/0162707 A1
(43) Pub. Date: Jul. 7, 2011

(54) ELECTRICAL CONTACT WITH ANTI TARNISH OXIDE COATING

(75) Inventors: Mikael Schuisky, Sandviken (SE); Sara Wiklund, Gavle (SE)

(73) Assignee: Sandvik Intellectual Property AB, Sandviken (SE)

(21) Appl. No.: 13/002,737

(22) PCT Filed: Jul. 3, 2009
(86) PCT No.: PCT/SE2009/050866

§ 371 Date: Mar. 21, 2011

(30) Foreign Application Priority Data
Jul. 7, 2008 (SE) 0801624-8

(51) Int. Cl. H01L 31/0224; H01R 13/03

(52) U.S. Cl. 136/256; 439/886

(57) ABSTRACT

The invention relates to an electrical contact t comprising a strip substrate comprising a conductive layer of a metal or an alloy provided on the surface of the substrate and an oxide layer provided on the conductive layer. By means of the oxide layer the underlying metal or alloy layer is protected from reaction with elements such as oxide or sulphur in the ambient air. The invention also relates to products such as fuel cells and solar cells comprising the electrical contact.

### TECHNICAL FIELD

The present invention relates to an electrical contact comprising a substrate and a conductive layer.

### BACKGROUND ART

Metals are by far the largest group of elements; about 80% of all known elements are metals. They are mostly characterized by properties such as high density, high melting point and high electrical and thermal conductivity. They are also ductile and malleable, which together with the other properties make them a very common engineering material and useful in many applications. In electrical applications, the metals silver, copper and gold are often used as contact material due to their high electrical conductivity. Most pure metals are however either too soft, brittle or chemically reactive to be used without modifications, which is why they are often alloyed with other elements. Some pure metals are also very expensive.

Pure copper, for example, will react with humid air as well as sulphides in the air to form copper oxides and sulphides, respectively, this will be seen as a green or black layer on the surface. One way to prevent this is to alloy copper with mainly zinc and tin respectively, thus achieving so called brasses or bronzes.

Pure silver is shiny, soft and has the highest electrical conductivity of all metals. Silver, however, suffers from discoloration when exposed to air, due to reactions with sulphides. This result in the formation of silver sulphide, Ag₂S, which appears as a dark layer on the surface, commonly referred to as tarnish.

The tarnish rate of silver is highly dependent on the content of sulphur compounds of the ambient air and consequently on the environmental pollution. If a piece of silver is kept in a polluted urban environment it can obtain a dark discoloration in only a few months. The main chemical reaction that results in tarnishing is:

2Ag+H₂S+½O₂=>Ag₂S+H₂O

However, other reactions involving oxides and sulphates also contribute to the tarnish to some amount.

In order to increase the hardness of silver, it has since long been alloyed with copper. Sterling silver is a common alloy consisting of at least 92.5 wt. % silver and 7.5 wt. % other metals, usually copper. However, alloying with copper further reduces the tarnish resistance, making the silver alloy even more prone to be discoloured. Tarnish may also affect the conductivity of the material, although it has not been fully explained to what extent.

Products comprising combinations of layers of metals with different properties are known. For example products comprising a layer of metal with high electrical conductivity, such as copper or silver, on an inexpensive substrate of high mechanical strength, such as steel. However, the silver layer in this type of products tarnishes easily during exposure to air. In the field of consumer electronics, such tarnished products are regarded less desirable by the customer, and may even be conceived by the customer as having inferior performance. Further drawbacks with such products include poor adhesion of the electrically conductive layer to the substrate as well as low wear resistance of the coating.

There is a need for an electrical contact with good electrical properties, which has a surface that is resistant to reactions with elements in the environment of the product, and which electrical contact does not suffer from the above drawbacks.

### SUMMARY OF THE INVENTION

It is an object of the present invention to provide an electrical contact with good electrical and mechanical properties, which has a surface that is resistant to reactions with elements in the environment of the electrical contact. The coating should be wear resistant and have good adhesion to the underlying substrate. Further objects of the present invention are to provide an interconnector for fuel cells or a back contact for thin film solar cells.

The problem is solved by the electrical contact as defined in claim 1, the fuel cell interconnector as defined by claim 9, and the solar cell back contact as defined by claim 10.

The invention provides an electrical contact comprising a strip substrate and a conductive layer of a metal or an alloy provided on the surface of said substrate, and an oxide layer provided on the conductive layer. By means of the oxide layer the underlying metal or alloy layer is protected from reaction with elements such as oxygen or sulphur in the ambient air. Yet, the oxide layer has a brittle nature which provides for easy penetration by e.g. a contact element, thus making the product excellent for use in electrical applications. The oxide layer is a sacrificial layer, which protects the electrical contact from tarnishing during storage, and which cracks when the electrical contact is used to enable a conductive contact.

The conductive layer is a metal layer or an alloy layer which may have an electrical conductivity greater than 0.1·10⁶ (cmΩ)⁻¹. An electrical contact comprising such a conductive layer exhibits good electrical properties. Preferably, the conductive layer has an electrical conductivity greater than 0.16·10⁶ (cmΩ)⁻¹ or even more preferably greater than 0.3·10⁶ (cmΩ)⁻¹. Such a layer exhibit very good electrical properties.

The conductive metal layer may be any of the following metals Ag, Cu, Au, Al which are excellent conductors. The conductive metal layer may also be alloys of these metals, for example AgCu (sterling silver).

The protective oxide layer may be anyone of SiO₂, TiO₂ or Al₂O₃, or a non-stoichiometric suboxide of SiO₂ such as SiOₓ (x<2), or a non-stoichiometric suboxide of TiO₂, such as TiOₓ (x<2), or a non-stoichiometric suboxide of Al₂O₃, such as Al₂Oₓ (x<3), or a mixture thereof. These oxides are transparent and provide a dense layer with very good adherence to the underlying conducting layer, thus providing good protection against corrosion by elements in the environment.

An oxide layer with a thickness of at least 5 nm, preferably at least 10 nm, and a maximum thickness of 100 nm, preferably max 50 nm, more preferably max 30 nm, protects the underlying surface from reaction with elements in the air but does not essentially influence the reflectivity of the underlying surface, which appears to be uncoated to the eye.

Coating metallic surfaces with SiO₂ or TiO₂ has earlier been used to protect articles, such as gold jewelry, from corrosion and abrasion. This is further described in U.S. Pat. No. 4,553,605. A thickness of the protective film of more than 1.5 μm is required to provide adequate protection.

The electrical contact may comprise a layer of nickel or titanium closest to the substrate, between the substrate and the conducting layer. The nickel or titanium layer provides for improved adhesion of the layers to the substrate. The invention also relates to a method for producing a an electrical contact, comprising the steps of: providing a strip substrate; ion-etching of the surface of the substrate; depositing a conductive layer of a metal or an alloy on the substrate; depositing a layer of oxide on top of the conductive layer. The method provides for effective and inexpensive manufacturing of an electrical contact which has an oxide layer protecting the underlying metal layer from reaction with elements such as oxygen or sulphur in the air.

Preferably, the layers are deposited by electron beam evaporation (EB) under reduced pressure in a continuous roll-to-roll process including in-line ion-etching of the substrate. By performing ion-etching of the surface of the substrate and EB-depositing the layers under reduced pressure in a continuous roll-to-roll process it is ensured that the layers are deposited directly onto the fresh, un-oxidized strip surface as well as directly onto each other without contact with air. This provides for very dense layers, which have excellent adherence to each other and to the substrate. Good wear resistance of the electrical contact is thereby achieved.

The nickel or titanium layer, and the conductive metal or alloy layers are preferably deposited under a maximum pressure of 1·10⁻² mbar with no addition of any reactive gas, whereby essentially pure metal layers are achieved.

The deposition of the protective oxide layer is preferably performed under reduced pressure with a partial pressure of oxygen in the range of 1·10⁻⁴-100·10⁻⁴ mbar. As reactive gas H₂O, O₂ or O₃ may be used, preferably O₂.

The EB evaporation may be plasma activated to further ensure hard and dense layers.

The electrical contact may also be manufactured in a stationary process wherein the substrate is first subjected to ion-etching and the layers thereafter are deposited on the substrate by physical vapour deposition (PVD) under a vacuum of 10⁴-10⁻⁸ mbar.

The invention also relates to a product for use in electrical applications utilizing the electrical contact according to the invention, including interconnectors in fuel cells and back contacts in thin film solar cells. Such a product exhibits very good electrical properties, such as high electrical conductivity and good contact resistivity. The oxide coating provides protection for the underlying metal surface from reactions with elements in the air and can easily be penetrated by a contact element, thus providing good electrical contact. The oxide layer is so thin so it does not essentially influence the reflectivity of the underlying surface, which appear as uncoated to the eye. Thereby is achieved a product with good electrical properties, the product can be stored for a long period of time without any change of the surface properties of the product. Thus, after storage the surface of the product will still exhibit maintained electrical properties and appear as new to the customer. In electronic applications a form of activation, e.g. penetration with a contact element, is needed to break the top coat, thereafter the contact resistance is equal to, or at least very close to, that of an uncoated conductive layer.

### BRIEF DESCRIPTION OF THE DRAWINGS

FIG. 1 schematically illustrates a cross-section of electrical contact according to the invention.

FIG. 2 schematically illustrates a cross-section of an electrical contact according to the invention including an adhesive nickel or titanium layer.

FIG. 3 schematically illustrates the method for manufacturing an electrical contact according to the invention.

FIG. 4 schematically illustrates a continuous method for manufacturing of the electrical contact according to the invention.

FIG. 5 schematically illustrates a stationary method for manufacturing of the electrical contact according to the invention.

FIG. 6 illustrates the results from tarnishing tests on samples No. 1, 2, 3, and 7 of the electrical contact according to the invention.

FIG. 7 illustrates the results from tarnishing tests on samples No. 1, 4, 5, and 6 of the electrical contact according to the invention.

FIG. 8 illustrates the results from reflectivity tests on samples No. 1, 2, 3, and 7 of the electrical contact according to the invention.

FIG. 9 illustrates the results from reflectivity tests on samples No. 1, 4, 5, and 6 of the electrical contact according to the invention.

FIG. 10 illustrates the results from contact resistance tests on samples No. 1, 2, 3, and 7 of the electrical contact according to the invention.

FIG. 11 illustrates the results from contact resistance tests on samples No. 1, 4, 5, and 6 of the electrical contact according to the invention.

FIG. 12 illustrates the results from contact resistance tests on samples No. 8-12 of the electrical contact according to the invention.

### DETAILED DESCRIPTION

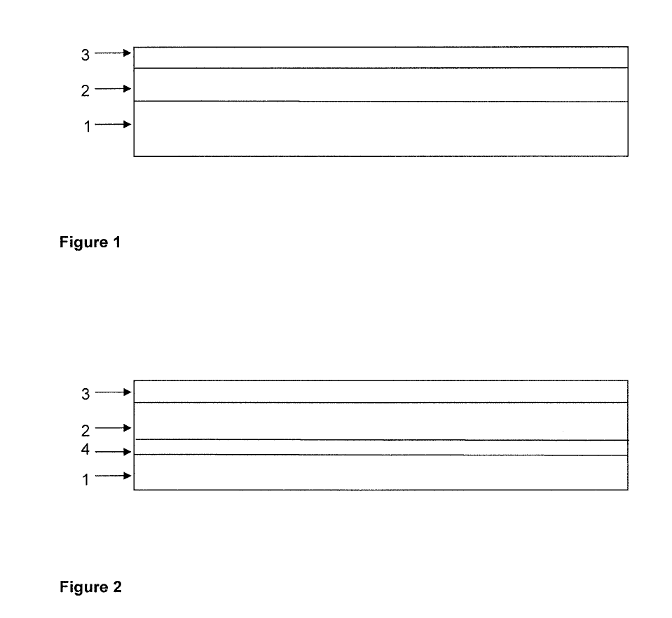

FIG. 1 illustrates a cross-section of an electrical contact according to the invention. The electrical contact comprises a substrate 1, a conductive layer 2 and a protective oxide layer 3. The substrate 1 may be of any type of steel, a martensitic stainless, chromium steel or an austenitic stainless steel but other metallic materials might also be used as a substrate, for example copper and copper alloys, nickel and nickel alloys. The substrate may be of any thickness suitable for the application intended, e.g. 0.03-5.0 mm, preferable not thicker than 1 mm or even more preferred less than 0.8 mm in thickness and have a width of maximum 2000 mm, preferably 800 mm.

Typically, the substrate is in the form of a continuous strip having a length from 1 meter up to several thousand meters and is provided in a coil. However, the substrate could also be in the form of plates or sheets.

The conductive layer 2 is applied on top of the substrate. The conductive layer should exhibit good electrical conductivity.

Electrical conductivity or specific conductivity is a measure of a material's ability to conduct an electric current. Conductivity is the reciprocal (inverse) of electrical resistivity and has the SI units of Siemens per meter (S·m⁻¹). Alternatively the units (cmΩ)⁻¹ are utilized. Based on their ability to conduct current, materials can be divided into conducting or insulating materials among which metals belong to the conducting materials. A good conductor, suitable for electrical applications, normally has an electrical conductivity measured at room temperature of at least 0.1·10⁶ (mΩ)⁻¹, preferably greater than 0.16·10⁶ (cmΩ)⁻¹, or even more preferably 0.3·10⁶ (cmΩ)⁻¹.

The conductive layer 2 comprises a pure metal, such as silver (Ag) which has the highest conductivity of all metals (0.63·10⁶/(cmΩ)⁻¹), copper (Cu) (0.596·10⁶ (cmΩ)⁻¹), gold (Au) (0.452·10⁶ (cmΩ)⁻¹) or aluminium (Al) (0.377·10⁶ (cmΩ)⁻¹) all conductivities measured at room temperature. Alternatively, the conductive layer is an alloy of a selection of the above mentioned metals. The thickness of the conductive layer could be up to several hundred microns but preferably it is less than 10 microns.

The oxide layer 3 is applied on top of the conductive layer and acts as a sacrificial layer, which protects the electrical contact from tarnishing. The protective oxide layer may be anyone of SiO₂, TiO₂ or Al₂O₃, or a non-stoichiometric suboxide of SiO₂ such as SiOₓ (x<2), or a non-stoichiometric suboxide of TiO₂, such as TiOₓ (x<2), or a non-stoichiometric suboxide of Al₂O₃, such as Al₂Oₓ (x<3), or a mixture thereof.

The oxide/oxides in the oxide layer are carefully chosen with respect to brittleness, transparency, and adhesion to underlying surface and the thickness dimension of the oxide layer is carefully controlled. A dense, transparent oxide layer with good adhesion to the underlying surface is thereby achieved. The oxide layer protects the underlying conducting layer from reaction with elements in the air which would cause the metal surface of the conductive layer to oxidize or tarnish.

An oxide layer with a thickness of at least 5 nm, preferably at least 10 nm, and a maximum thickness of 100 nm, preferably max 50 nm, more preferably max 30 nm, protects the underlying surface from reaction with elements in the ambient air. However, the thickness of the oxide layer is not greater than that the reflectivity of the underlying surface remain essentially unchanged so that the surface of the conductive metal or alloy layer appears to be clean and uncoated to the eye. The oxide layer is brittle and cannot withstand penetrating forces exerted on the oxide surface. The brittleness in combination with the low thickness of the oxide layer makes it easy to penetrate with e.g. a contact element, thus establishing electrical contact with the conductive layer. If the thickness of the oxide layer is too thin the conductive coating will not be protected effectively enough, and the coating will oxidize or tarnish. Furthermore, for very thin layers (<5 nm) it will be very difficult to achieve a uniform coating when the electrical contact is manufactured in a production scale. If the oxide layer is too thick, too much load will be needed to penetrate the protective layer with e.g. a contact element, resulting in a electrical contact that does not function satisfactory.

The electrical contact may comprise a layer of nickel (Ni) or titanium (Ti) 4, applied directly on top of the surface of the substrate such as described in FIG. 2. The nickel or titanium layer 4 provides for improved adhesion between the substrate 1 and the subsequent layers. The nickel or titanium layer 4 should be thick enough to provide good adhesion to the underlying surface. Normally the thickness should be 50-1000 nm, preferably less than 200 nm. A conductive metal layer 2, as described above, is provided on top of the nickel or titanium layer and a protective oxide layer 3, as described above, is provided on top of the conductive metal layer 2.

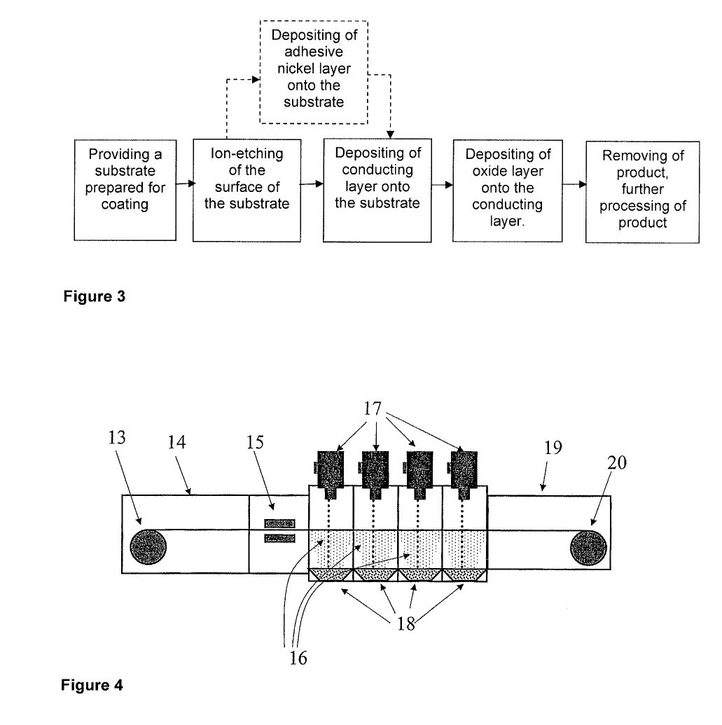

FIG. 3 schematically describes the steps of the method for producing an electrical contact according to the invention. The method comprises the following steps:
a) Cleaning of the substrate in order to remove oil and grease residues from the strip rolling process. Thus, providing a substrate which is prepared for coating.
b) Ion-etching of the surface of the substrate.
c) Depositing a conductive layer on the surface of the substrate.
d) Depositing an oxide layer on the conductive layer.
e) Subjecting the substrate to further processing into a component.

A nickel or titanium layer could optionally first be deposited directly on the surface of the substrate as described with dashed lines in FIG. 3.

A variety of physical or chemical vapour deposition methods may be used to apply the different layers on the substrate. Both continuous and stationary processes could be used. As examples of different deposition methods can be mentioned chemical vapour deposition (CVD), metal organic chemical vapour deposition (MOCVD), physical vapour deposition (PVD) such as sputtering and evaporation by resistive heating, by electron beam, by induction, by arc resistance or by laser evaporation.

For the present invention it is preferred to deposit the layers by electron beam evaporation (EB) under reduced pressure in a continuous roll-to-roll process including in-line ion-etching of the substrate. A roll-to-roll arrangement including ion-etching and electron beam (EB) evaporation chambers as described in FIG. 4 is used to deposit the layers on the substrate.

The roll-to-roll electron beam evaporation arrangement described in FIG. 4 comprises a first vacuum chamber 14 in which an un-coiler 13 for un-coiling a strip shaped substrate is arranged. In pressure tight connection to the first vacuum chamber is arranged an in-line ion assisted etching chamber 15 followed by a series of EB-evaporation chambers 16. The number of EB-evaporation chambers can vary from 1 to 10 chambers in order to deposit several layers on the substrate. All the EB-evaporation chambers 16 are equipped with EB-guns 17 and water cooled copper crucibles 18 for the material to be deposited. The exit of the last chamber is in pressure tight connection to a second vacuum chamber 19 in which a re-coiler 20 is arranged to coil the coated strip substrate. The vacuum chambers 14 and 19 could be replaced by an entrance vacuum lock system and an exit vacuum lock system. In this case, the un-coiler 13 and the re-coiler 20 are placed in the open air.

According to the method a coil of a strip shaped substrate is provided. First of all the surface of the substrate material is cleaned in a proper way to remove all oil residues, which otherwise may negatively affect the efficiency of the coating process and the adhesion and the quality of the coating.

Thereafter the strip is placed in the roll-to-roll arrangement and a vacuum is provided in the first and the second vacuum chambers 14, 19. The strip is continuously un-coiled from un-coiler 13 and is first etched in the ion-etching chamber 15 The ion-etching removes the very thin native oxide layer that is normally always present on a steel surface, thereby is achieved a fresh metal surface on the substrate which provides for very good adhesion of the first layer.

The substrate is thereafter coated in the EB-evaporation chambers 16. In EB-evaporation, the coating material is heated by means of an electron beam from an electron source, focused into the coating material. The focused heat causes the coating material to evaporate. The evaporated coating material is then adsorbed on the surface of the substrate and gradually builds up a coating. Several EB-chambers may be arranged in-line. In the first chamber an adhesive layer of nickel or titanium may be deposited on the substrate, in the second chamber is a conductive layer of metal or metal alloy deposited and in the third chamber is a protective oxide layers deposited. The deposition of an adhesion promoting nickel or titanium layer and the conductive layer of metal or metal alloy should be made under reduced atmosphere at a maximum pressure of 1·10⁻² mbar with no addition of any reactive gas to ensure essentially pure metal layers. The deposition of the protective oxide layer should be performed under reduced pressure with a reactive gas from an oxygen source in the chamber. The partial pressure of oxygen should be in the range of 1·10⁻⁴-100·10⁻⁴ mbar. As reactive gas H₂O, O₂ or O₃ may be used, preferably O₂. The reactive EB evaporation may be plasma activated to further ensure hard and dense layers.

Finally, the coated substrate is coiled on the re-coiler 20. The substrate may subsequently be subjected to further processing such as slitting or stamping into a component of desired shape.

The roll-to-roll deposition arrangement may advantageously be integrated in a strip production line.

If the conductive layer is a metal alloy, co-evaporation could be used to deposit the alloy on the substrate. In co-evaporation, separate crucibles for every element in the alloy are utilized in the deposition chamber. The elements are then simultaneously evaporated from the crucibles to form an alloy as they hit the substrate. Thus, materials that normally do not solve in each other can be coated onto a substrate at the same time.

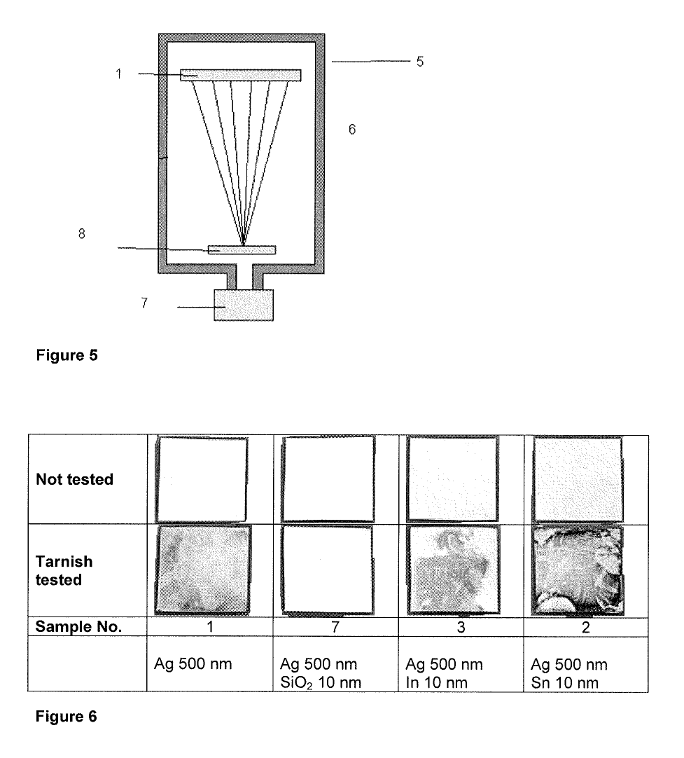

If the substrate is in the form of sheets or plates a stationary process as described in FIG. 5 could be used. The pieces are first cleaned in order to remove oil residues, and are thereafter placed in a substrate holder in a chamber 5 of a PVD apparatus 6. A vacuum of 10⁻⁴-10⁻⁸ mbar is provided in the PVD chamber and the substrate is first subjected to ion-etching in order to remove the thin oxide layer on the surface. Next, the substrate is coated with the different layers starting with the nickel or titanium layer (if desired), then the conductive layer and finally the oxide layer. Each coating material 8 is contained inside the chamber 5 opposite the substrate 1. Normally, the coating materials are provided in the form of ingots or in crucibles. The high vacuum may be maintained throughout the coating process, however it is also possible to use controlled amounts of gases e.g. in order to create a plasma. Finally, the substrate is removed from the PVD chamber and subjected to further processing, such as slitting, cutting or stamping.

Heating of the substrate can improve the adhesion of the coating by allowing the atoms to find more energetically favourable positions. A substrate in the form of a discrete piece may be rotated in order to achieve uniform thickness of the coating.

### Example 1

Following is an example of the manufacturing of an electrical contact according to the invention. The example also show results from measurements made on the electrical contact.

### Preparation

As substrate material a 0.08 mm thick stainless steel strip of the alloy ASTM 301 was used. The strip was cut into pieces of 300×150 mm to fit the substrate holders in the deposition chamber of a PVD apparatus. The pieces were cleaned using the following steps:
Ultrasonic cleaning in a lye bath for 10 minutes at 60° C.
Rinse in warm tap water
Rinse in de-ionized water
Rinse in ethanol
Drying with compressed air

The pieces were handled with gloves to avoid contaminations.

The ingots to be used in the processes were prepared in crucibles.

### Deposition of Coatings

The ingots to be used for deposition were placed in the vacuum chamber together with a nickel ingot and two steel substrates. An automatic coating process was programmed into the control system of the PVD apparatus. The automatic coating process was initiated when the pressure in the chamber had reached 1.0∩10⁻⁵ mbar. The process included an initial four minutes sputtering with argon gas to further clean the substrates, which were heated and rotated. A 50 nm thick nickel layer was first deposited directly onto the substrate to improve the adhesion of the following layers. A layer of pure silver of a thickness of 500 nm was then deposited. On top of the silver layer a top coating was deposited. The oxide SiO₂ was used as top coating as well as the metals Sn, In and Ge for comparison. The thickness of the top coatings was ranging from 5 to 25 nm. As further comparison, samples were prepared with a pure silver layer left uncoated. Two substrates were coated in each process. The coatings are shown in table 1.

TABLE 1

| | | | | Conductive | | |
|---|---|---|---|---|---|---|
| | | Ni-layer | | layer | | Top coat |
| Sample | | thickness | Conductive | thickness | Top coat | thickness |
| No. | Substrate | (nm) | layer | (nm) | element | (nm) |
| 1 | ASTM 301 | 50 | Ag | 500 | — | — |
| 2 | ASTM 301 | 50 | Ag | 500 | Sn | 10 |
| 3 | ASTM 301 | 50 | Ag | 500 | In | 10 |
| 4 | ASTM 301 | 50 | Ag | 500 | Ge | 5 |
| 5 | ASTM 301 | 50 | Ag | 500 | Ge | 10 |
| 6 | ASTM 301 | 50 | Ag | 500 | Ge | 25 |
| 7 | ASTM 301 | 50 | Ag | 500 | SiO2 | 10 |

### Analyses

The following analyses where made on the samples of the coated substrates.

### Tarnish Resistance

Samples of the coated substrates were placed in a sealed glass container with a volume of 20 L. A beaker with 20 g Na₂S was also placed in the container. After 24 hours, the samples were removed from the container and visually inspected.

### Reflectivity

Sheen GlossMaster 60° was used to measure the reflectivity of the coatings. The device determines the gloss of a 15×9 mm area of a sample at 60° angle of incidence, and gives the result in gloss units. Since the gloss units range between 0 and 100, the result can be interpreted as reflectivity percentage. The wavelengths used in the device are defined between 380-770 nm, i.e. in the visible part of the electromagnetic spectrum.

### Contact Resistance

Strips with dimensions 300×20 mm were cut from the samples to be used for the resistance test. In the test set-up, a Zwick/Roell load machine and a Burster Resistomat 2318 ohmmeter was used. Software TestXpert II was used to process the data. The measurements were performed according to the ASTM standard ASTM B667-97. The measuring probe was placed near the surface of the strip and then automatically pushed down, applying increasing predetermined loads while continuously recording the resistance. Waiting time at each of the 26 load points was set to 10 seconds and the final load was 100 N.

### Adhesion

The adhesion of the coatings was tested using standardized method SS-EN ISO 2409. It consists of a cutting device with six sharp and parallel edges that create a grid when two perpendicular cuts are made. A special tape is placed over the grid and removed by hand. The grid is then visually inspected and graded on a scale from 0-5 depending on the amount of affected coating material. The grade “0” is an unaffected surface with very good adhesion, while “5” means that a majority of the surface material has come off.

### Results

### Tarnish Test

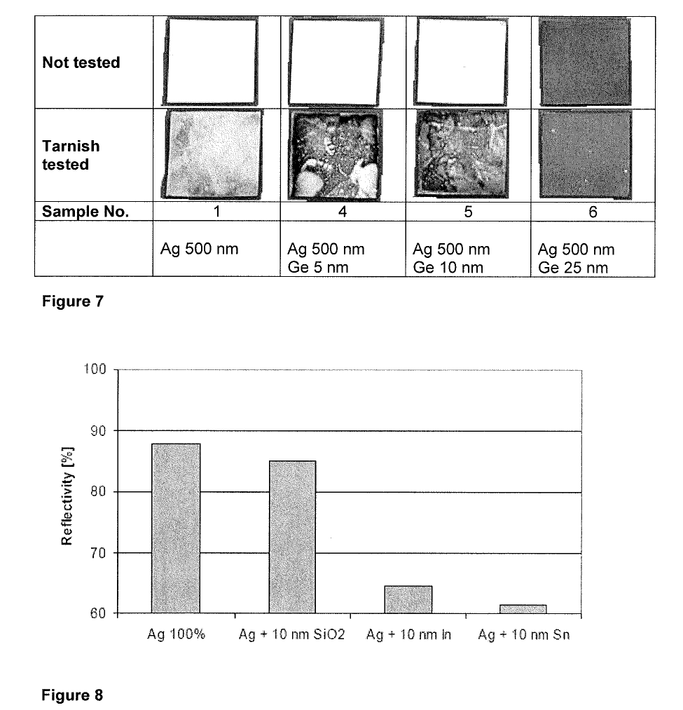

The results of the tarnish test are presented in FIGS. 6 and 7. As can be seen in FIG. 6, sample No. 7, which had a top coat of SiO₂, provided the best tarnish resistance.

### Reflectivity

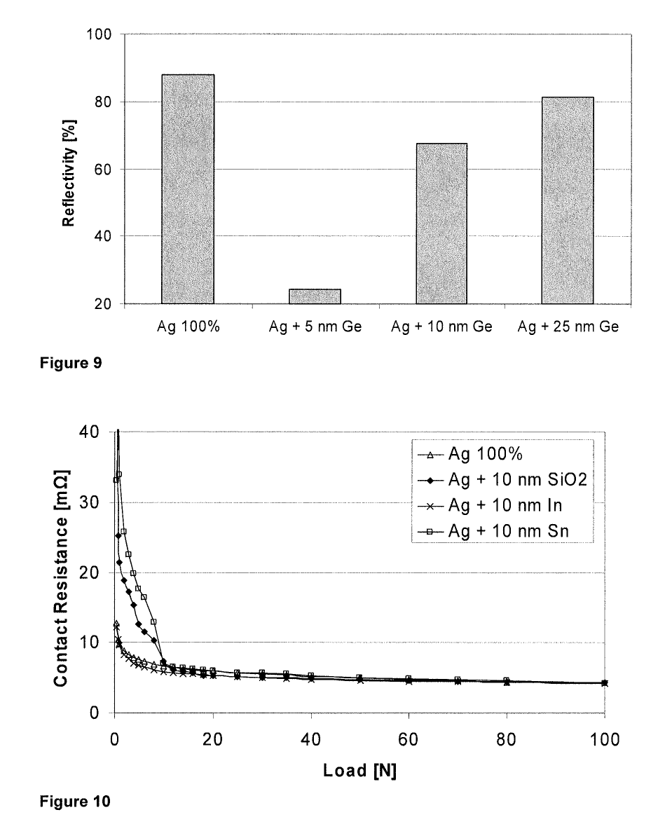

The reflectivity was measured five times on each substrate. The average values are presented in FIGS. 8 and 9. It can be seen in FIG. 8 that the SiO₂ coat did practically not affect the reflectivity at all.

### Contact Resistance

Contact resistance tests were carried out on the samples and the results are presented in FIGS. 10 and 11. Several tests were performed on each sample, and the curve that best represented the sample was chosen to be presented. The result for pure silver is also included in the diagram for comparison. It can be seen in FIG. 10 that a load of 10-15 N is sufficient to break the oxide layer. At this load the contact resistance is approximately the same for the reference sample with an Ag coating, and the samples having top coats.

### Adhesion

The adhesion test showed that all coatings, had very good adhesion, grade “0” in the test.

### Example 2

Following is an example of the manufacturing of an electrical contact according to the invention. The example also show results from measurements made on the electrical contact.

### Preparation and Deposition of Coatings

The ingots to be used for deposition were placed in the vacuum chamber together with a titanium ingot and two steel substrates. An automatic coating process was programmed into the control system of the PVD apparatus. The automatic coating process was initiated when the pressure in the chamber had reached 1.0·10⁻⁵ mbar. The process included an initial four minutes sputtering with argon gas to further clean the substrates, which were heated and rotated. A 100 nm thick titanium layer was first deposited directly onto the substrate to improve the adhesion of the following layers. A layer of pure silver of a thickness of 1000 nm was then deposited. On top of the silver layer a top coating was deposited. The oxide SiO₂ was used as top coating. The thickness of the top coatings was ranging from 10 to 100 nm. For comparison, two samples were prepared with no top coat; one sample with a conductive coating of silver and one sample with a conductive coating of silver-indium (AgIn). Two substrates were coated in each process. The coatings are shown in Table 2.

TABLE 2

| | | | | Con- | | |
|---|---|---|---|---|---|---|
| | | Ti-layer | | ductive | | |
| Sam- | | thick- | Con- | layer | Top | Top coat |
| ple | | ness | ductive | thickness | coat | thickness |
| No. | Substrate | (nm) | layer | (nm) | element | (nm) |
| 8 | ASTM 301 | 100 | Ag | 1000 | SiO₂ | 10 |
| 9 | ASTM 301 | 100 | Ag | 1000 | SiO₂ | 30 |
| 10 | ASTM 301 | 100 | Ag | 1000 | SiO₂ | 100 |
| 11 | ASTM 301 | 100 | Agln* | 1000 | — | — |
| 12 | ASTM 301 | 100 | Ag | 1000 | — | — |

*Ag 97 wt % In 3 wt %

### Analyses

### Tarnish Resistance

Samples of the coated substrates were tested according to the ISO standard SS-EN ISO 12687. The samples were removed from the container and visually inspected after 4, 24, 48 and 168 h.

### Contact Resistance

Analyses of the contact resistance were performed as described in Example 1.

### Results

### Tarnish Tests

The results of the tarnish test are presented in Table 3. Sample No. 10 provided the best tarnish resistance. The samples with no SiO₂-coating, samples No. 11 and 12, were visibly tarnished after only 4 h and heavily tarnished after 48 h.

TABLE 3

| | Sample No. | | | | |
|---|---|---|---|---|---|
| Test time | 8 | 9 | 10 | 11 | 12 |
| 4 h | Unaffected | Unaffected | Unaffected | Minor tarnish | Minor tarnish |
| | | | | around | around |
| | | | | edges | edges |
| 24 h | Unaffected | Unaffected | Unaffected | Edges | Edges |
| | | | | tarnished. | tarnished. |
| | | | | Area closest | Area closest |
| | | | | to the | to the |
| | | | | sulphur more | sulphur more |
| | | | | affected. | affected. |
| 48 h | Yellowing of | Yellowing of | Traces of | Heavily | Heavily |
| | the surface | the surface. | yellowing | tarnished. | tarnished. |
| | and some | | around | | |
| | tarnish | | edges | | |
| | blemishes. | | | | |
| 168 h | Brownish | Yellowing | Very light | Completely | Completely |
| | surface | and | discoloration | tarnished. | tarnished. |
| | abundance | blemished | and a few | | |
| | of blemishes. | surface. | blemished at | | |
| | | | edges. | | |

### Contact Resistance

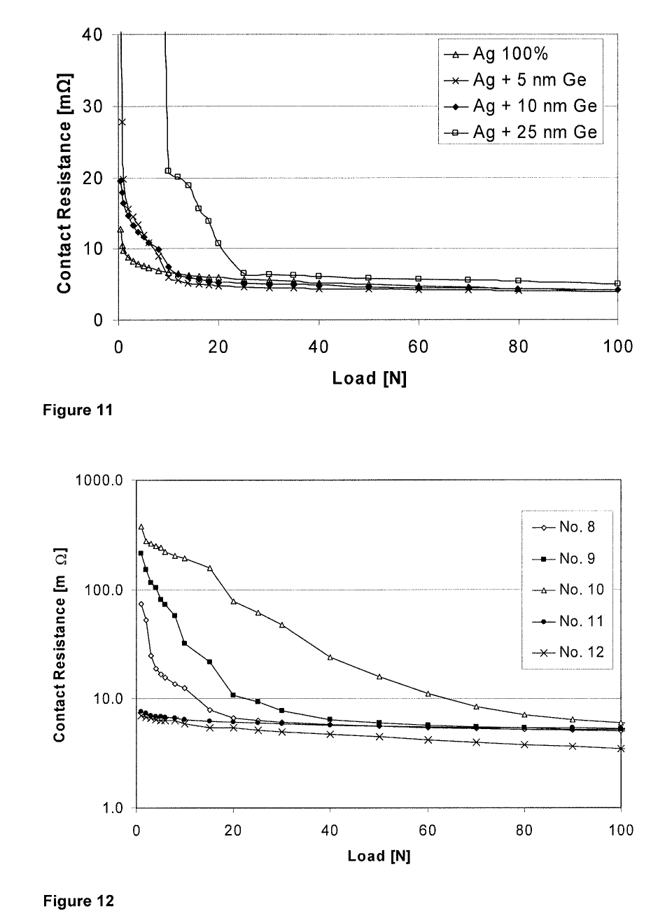

The results from the contact resistance tests are presented in FIG. 12. The data points in the figure represent the average value of five measurements on each sample. Increased thickness of the SiO₂ top coating results in an increased contact resistance at low load. As shown in FIG. 12 both Sample No. 8 and No. 9, with 10 and 30 nm SiO₂ layer respectively, have good contact resistance properties. For the sample with the thickest SiO₂ coating, sample No. 10, more load is needed to achieve an acceptable contact resistance. However, the thick SiO₂ layer can be penetrated by repeated loads with low force.

The contact resistance depends on the choice of substrate, the thickness of the coating as well as on external conditions, such as humidity. The contact resistance that is needed for the final product to function properly is closely dependant on the application. For some applications a low contact resistance at low loads is important. For other applications a low contact resistance at a higher load is acceptable. A thicker top coat layer will give a better protection against tarnishing than a thinner top coat. For applications wherein the electrical contact is to be used in environments which are not so sensitive to the applied load a thicker top coat will result in a possibility for longer storage times without the electrical contact suffering from tarnishing.

Although particular embodiments have been disclosed herein in detail, this has been done for purposes of illustration only, and is not intended to be limiting with respect to the appended claims. It is obvious that the settings and parameters for controlling the processes described above differs from one case to another and that these settings and parameters are determined by a person skilled in the art. The disclosed embodiments can also be combined. In particular, it is contemplated by the inventors that various substitutions, alterations, and modifications may be made to the invention without departing from the scope of the invention as defined by the claims

1. An electrical contact comprising:
a strip substrate,
a conductive layer, comprising a metal or an alloy, provided on a surface of said substrate, and
a sacrificial layer provided on the surface of the conductive layer,
wherein the sacrificial layer is an oxide layer with a thickness of 5-100 nm, which sacrificial layer protects the electrical contact from tarnishing and which is penetrable at electrical contacting.

2. The electrical contact according to claim 1 wherein the conductive layer has an electrical conductivity greater than 0.1·10⁶ (cmΩ)⁻¹.

3. The electrical contact according to claim 1 wherein the conductive layer comprises any of Ag, Cu, Au, Al, or alloys of these metals.

4. The electrical contact according to claim 1 wherein the sacrificial layer is formed of any of SiO₂, TiO₂ or Al₂O₃, or a non-stoichiometric suboxide of SiO₂ or a non-stoichiometric suboxide of TiO₂, or a non-stoichiometric suboxide of Al₂O₃, or a mixture thereof.

5. The electrical contact according to claim 1 wherein the thickness of the oxide layer is 10-100 nm.

6. The electrical contact according to claim 5 wherein the thickness of the oxide layer is 10-50 nm.

7. The electrical contact according to claim 6 wherein the thickness of the oxide layer is 10-30 nm

8. The electrical contact according to claim 1 comprising a layer of Ni or Ti between the strip substrate and the conductive layer.

9. A fuel cell interconnector, comprising an electrical contact including a strip substrate, a conductive layer, comprising a metal or an alloy, provided on a surface of said substrate, and a sacrificial layer provided on the surface of the conductive layer, wherein the sacrificial layer is an oxide layer with a thickness of 5-100 nm, which sacrificial layer protects the electrical contact from tarnishing and which is penetrable at electrical contacting.

10. A solar cell back contact, comprising an electrical contact including a strip substrate, a conductive layer, comprising a metal or an alloy, provided on a surface of said substrate, and a sacrificial layer provided on the surface of the conductive layer, wherein the sacrificial layer is an oxide layer with a thickness of 5-100 nm, which sacrificial layer protects the electrical contact from tarnishing and which is penetrable at electrical contacting.
